(19) United States
(12) Patent Application Publication
(10) Pub. No.: US 2010/0096647 A1
(43) Pub. Date: Apr. 22, 2010

(54) LIGHT OUTPUT DEVICE

(75) Inventors: Maarten Marinus Johannes Wilhelmus Van Herpen, Eindhoven (NL); Coen Theodorus Hubertus Fransiscus Liedenbaum, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/593,311

(22) PCT Filed: Mar. 31, 2008
(86) PCT No.: PCT/IB2008/051202

§ 371 Date: Sep. 28, 2009

(30) Foreign Application Priority Data
Apr. 3, 2007 (EP) 07105533.9
Apr. 12, 2007 (EP) 07106007.3
May 3, 2007 (EP) 07107467.8

(51) Int. Cl. H01L 27/15; H01L 33/00

(52) U.S. Cl. 257/91; 438/27; 438/28; 257/E33.055; 257/E27.12

(57) ABSTRACT

A light output device comprises a substrate arrangement comprising first and second light transmissive substrates (1,2) and an electrode arrangement (3a,3b) sandwiched between the substrates. A plurality of light source devices (4) are integrated into the structure of the substrate arrangement and connected to the electrode arrangement. The electrode arrangement comprises an at least semi-transparent conductor arrangement of spaced non-transparent wires, the wires comprising a conductive ink.

### FIELD OF THE INVENTION

This invention relates to light output devices, in particular using discrete light sources associated with a light transmissive substrate structure.

### TECHNICAL BACKGROUND

One known example of this type of lighting device is a so-called “LED in glass” device. An example is shown in FIG. 1. Typically a glass plate is used, with a transparent conductive coating (for example ITO) forming electrodes. The conductive coating is patterned in order to make the electrodes, that are connected to a semiconductor LED device. The assembly is completed by laminating the glass, with the LEDs inside a thermoplastic layer (for example polyvinyl butyral, PVB).

Applications of this type of device are shelves, showcases, facades, office partitions, wall cladding, and decorative lighting. The lighting device can be used for illumination of other objects, for display of an image, or simply for decorative purposes.

One problem with the current LED in glass products is that the transparent conductive layer has a high electrical resistance, so that a lot of electrical power is lost. Furthermore, the ITO layers cannot be patterned to form very narrow conductor lines, because this would further increase the electrical resistance. There are proposed solutions to this problem, using a semi-transparent conductive mesh. For example, U.S. Pat. No. 5,218,351 discloses the use of a mesh of wires, acting as a (semi) transparent conductor. This requires a lithographic process, which is therefore difficult and expensive to produce on large scale and in large volumes.

### SUMMARY OF THE INVENTION

It is an object of the invention to provide a light output device having integrated light source devices in which a highly electrical conductive and highly transparent electrode arrangement can be provided with a low cost process.

According to the invention, there is provided a light output device comprising:

a substrate arrangement comprising:

first and second light transmissive substrates and an electrode arrangement sandwiched between the substrates; and

a plurality of light source devices integrated into the structure of the substrate arrangement and connected to the electrode arrangement,

wherein the electrode arrangement comprises an at least semi-transparent conductor arrangement of spaced non-transparent wires, the wires comprising a conductive ink.

The invention provides conductive wires, or a conductive mesh, produced using printing with highly conductive ink. Preferably, the conductivity is less than 0.1 Ohm/sq/mil and more preferably less than 0.75 Ohm/sq/mil.

The electrical resistance is suitable for light output applications and the wires may be placed in complex patterns without increasing electrical resistance.

The light transmissive substrate material may be transparent (optically clear) or a diffusive transmissive material.

The ink may comprise silver or other conducting particles, for example silver particles in a thermoplastic binder.

The light source devices are preferably spaced apart by at least 15 mm, and more preferably by more than 30 mm, and even more preferably more than 50 mm. The greater the spacing, the further apart the wires of the electrode pattern can be spaced, which improves the overall transparency.

The electrode arrangement preferably comprises a plurality of wires of width less than 1000 μm, more preferably less than 600 μm. The smaller the width, the greater the transparency. However, the width is preferably more than 75 μm to provide the required low resistance, for example more than 150 μm.

The light source device may comprise an LED device or a group of LED devices. For example, each device may be a group of three coloured LEDs, and the electrode pattern then comprises individual supply electrode lines leading to each LED and a shared drain electrode line or separate electrode lines leading from each light source device.

In addition to the semi-transparent electrode arrangement, a fully transparent conductor arrangement may be provided which connects to the electrode arrangement, for example using a transparent conductive oxide as transparent material, such as for example ITO.

The light source devices can comprise inorganic LEDs, organic LEDs, polymer LEDs or laser diodes.

The invention also provides a method of manufacturing a light output device, comprising:

printing an electrode arrangement onto one a first light transmissive substrate of a substrate arrangement, using an conductive ink, to define an at least semi-transparent conductor arrangement of non-transparent wires;

providing a plurality of light source devices connected to the electrode arrangement; and

providing a second light transmissive substrate, and sandwiching the electrode arrangement between the substrates, thereby integrating the light source devices within the structure of the substrate arrangement.

The two substrates can be bound together using a thermoplastic layer or resin, for example polyvinyl butyral (PVB) or an ultraviolet (UV) resin.

The printing can comprise silk screen printing, inkjet printing or offset printing.

### BRIEF DESCRIPTION OF THE DRAWINGS

Examples of the invention will now be described in detail with reference to the accompanying drawings, in which:

FIG. 1 shows a known LED in glass device;

FIG. 2 shows a single LED of the device of FIG. 1 in more detail and to which the invention can be applied;

FIG. 3 shows a first conductor arrangement layout of the invention;

FIG. 4 shows a second conductor arrangement layout of the invention; and

FIG. 5 shows a third conductor arrangement layout of the invention.

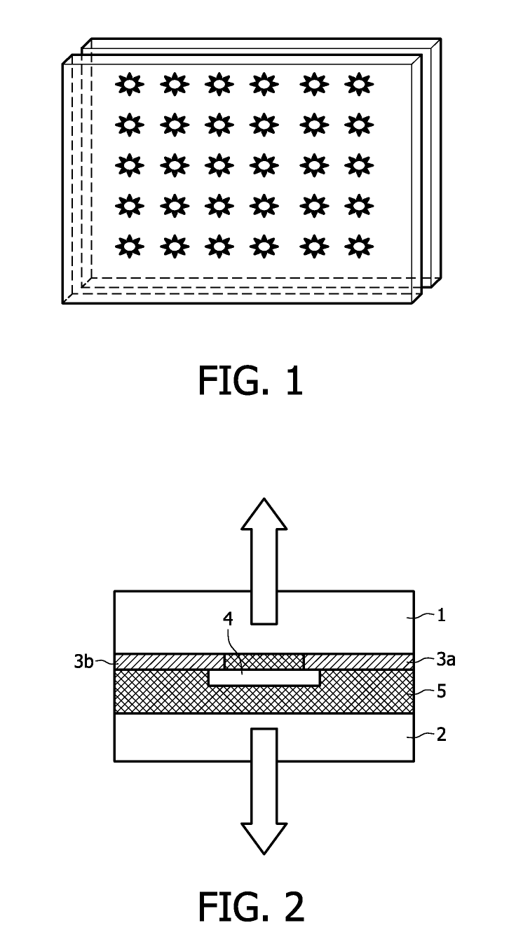

The same reference numbers are used to denote similar parts in the different figures.

### DETAILED DESCRIPTION OF EMBODIMENTS

The structure of a known LED in glass illumination device is shown in FIG. 2. The lighting device comprises glass plates 1 and 2. Between the glass plates are (semi-) transparent electrodes 3a and 3b (for example formed using ITO), and a LED 4 connected to the transparent electrodes 3a and 3b. A layer of thermoplastic material 5 is provided between glass plates 1 and 2 (for example PVB or UV resin).

The glass plates typically may have a thickness of 1.1 mm-2.1 mm. The spacing between the electrodes connecting to the LED is typically 0.01-3 mm, for example around 0.15 mm. The thermoplastic layer has a typical thickness of 0.3 mm-2 mm, and the electrical resistance of the electrodes is in the range 2-80 Ohm, or 10-30 Ohms/square. The electrodes are preferably substantially transparent, so that they are imperceptible to a viewer in normal use of the device. Preferably, the transparency is greater than 80%, more preferably 90%, and even more preferably 99%.

The invention provides a structure similar to the known structure of FIG. 2, but uses an electrode arrangement which comprises an at least semi-transparent conductor arrangement comprising spaced apart non-transparent wires formed using a conductive ink. The conductor arrangement can thus be printed.

Various printing methods may be used, and a presently preferred method is screen-printing, or serigraphy (previously known as Silkscreen printing). This is a printing technique that traditionally creates a sharp-edged image using a stencil and a porous fabric.

Glass plates with conductive screen-printed lines are known from the automobile industry, which has manufactured automobiles with rear windows including electrical heating elements to remove frost formed on the window surface. The rear windows are printed by a silkscreen printing process, with a grid of a metallic material which is then fired-on the glass window to form the electrical heating element.

In most instances, the grid arrangement forming the heating element is comprised of a bus bar extending along each side of the window, and a series of fine lines extending horizontally across the window, with the fine lines being connected to the bus bars. The grid material from which the heating element is formed is typically a mixture containing a silver powder and a small amount of soft-lead glass dispersed in a printing medium, such as oil suitable for silkscreen printing. The grid material is applied to the glass substrate in a silk-screen printing process.

The conductive wires made for automobile window heaters have a high electrical resistance. Due to this, such wires are not suited for connecting LEDs in glass, since this would lead to an unwanted loss of electrical power.

With reference to the known structure of FIG. 2, the invention uses electrodes 3a and 3b printed with a conductive ink, having a resistance and dimensions selected to provide a desired combination of overall transparency as well a low electrical resistance. In particular, the electrodes 3 are very thin, with a wide spacing between electrodes, so that the complete conductive structure is semi-transparent, with the desired high transparency mentioned above.

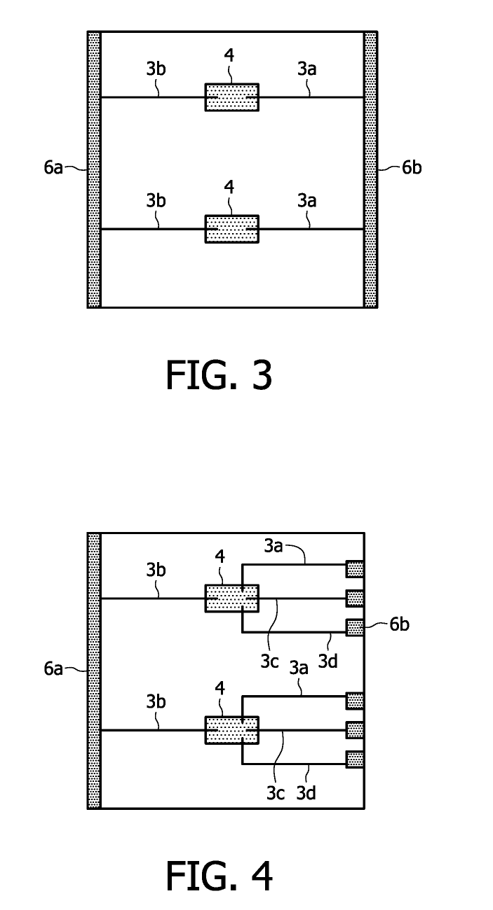

FIG. 3 shows a top-view of a structure according to the present invention, showing the printed electrodes 3a and 3b, two LEDs 4, and two bus bars 6a and 6b. By applying a voltage over the bus bars, a current will flow between the bus bars, through the electrodes and LEDs.

There are a number of design issues for the printed electrodes, and these are discussed in turn below.

### Composition of the Ink

Some examples of conductive inks are given in Table 1 below. In order to achieve a low electrical resistance for the wires, it is important to use a highly-conductive ink. Typically, a suitable ink comprises finely divided silver particles in a thermoplastic binder, the cured ink having a sheet resistance of less than 0.075Ω per square at 1 mil thickness (=0.025 mm).

TABLE 1
Examples of conductive inks.

| | | | |
|---|---|---|---|
| Electrodag 423SS | <42.0 | Ω/sq @ 1 mil | http://www.achesonindustries.com/doc/pds/Asia/ed_423ss.pdf |
| Electrodag SP-017 | 0.075 | Ω/sq/mil | http://www.laddresearch.com/SpecSheets/60830.pdf |
| Electrodag 18DB70X | <0.015 | Ω/sq/mil | http://www.thorlabs.com/Images/PDF/Vol18_739.pdf |
| Scientific | 0.010-0.005 | Ω/sq/mil | BANCROFT R |
| publication | | | CONDUCTIVE INK A MATCH FOR COPPER ANTENNA |
| Bancroft et al. | | | MICROWAVES & RF 26 (2): 87& FEB 1987 |
| | | | http://adsabs.harvard.edu/abs/1987MicWa..26...87B |

As seen in Table 1, not all inks are suited for this purpose. For example, Electrodag 423SS has a very high resistance, and is therefore only suitable in for example glass heating applications. The other inks listed in Table 1 are all suitable.

### Dimensions of the Wires

The best resolution currently achieved using screen-printing is typically 5 mil (125 μm).

In order to achieve a light transmission of 99% with a non-transparent wire width of 125 μm, this means that the spacing between the wires should be greater than 12.5 mm.

If thinner wires may be printed, for example having a width of 75 μm, the spacing may now be reduced to a minimum of 7.5 mm.

Typically, a spacing between LEDs is 60 mm. In that case, the wire width may be up to 600 μm. Similarly, if the LED spacing is 100 mm, the wire width may be up to 1000 μm, again to achieve the 99% transparency. Of course, there may be a lower requirement for transparency, which will allow wider electrode wires for a given spacing.

Depending on the preferred distance between the viewer and the glass, the wires are preferably sufficiently thin that they cannot be seen. In contrast to this, the wire is preferably as wide as possible, in order to reduce the electrical resistance.

### Resistance of the Wires

As mentioned above, the resistance of the wires should not be too high, because this leads to high loss of electrical power. The highest resistance that is still acceptable can be considered to be a resistance of the same order of magnitude as the LED resistance.

For example The Nicha white LED model NFSW036BT has a specified maximum current of 180 mA and a maximum power of 684 mW. From this, the typical resistance for this LED can be calculated to be 21 Ohm.

A preferred ink (in Table 1 above) is Electrodag 18 DB70X, having a conductivity of <0.015 Ωsq/mil. Using an example of typical LED spacing of 100 mm, the total resistance of a 100 mm long wire should therefore have a resistance of <21Ω.

The resistance may be calculated using:

$$R = ρ \frac{l}{A}$$

This formula relates the resistance (R) of a conductor with its specific resistance (ρ), its length (l), and its cross-sectional area (A). The specific resistance may be calculated from the square resistance, using:

ρ=R_{square}×d=0.015 Ω/sq·mil×1 mil=3.8×10⁻⁴ Ωmm

This gives:

$$R = 3.8 \times {10}^{- 4} Ωmm \times \frac{100 mm}{A} \leq 20 Ω$$

$$A \geq 3.8 \times {10}^{- 4 } Ωmm \times \frac{100 mm}{20 Ω} = 1.9 \times {10}^{3} {mm}^{2}$$

$$width \geq \frac{1.9 \times {10}^{3} {mm}^{2}}{1 mil} = 0.075 mm = 75 µm$$

In conclusion, for this ink, the smallest allowed width for the wire (using 1 mil coating thickness) is 75 μm=3 mil. By increasing this width, the electrical power losses may be further decreased.

Thus, a preferred wire width is >75 μm, with a wire thickness of 1 mil=25 μm. The preferred wire spacing is then 7.5 mm.

Of course, if the thickness can be increased, the width can be reduced accordingly.

For comparison, the dimensions of the ITO conductors used in prior art LEDs in glass is now explained. Using an ITO coating, a typical resistance of 25 Ohm applies for a 10×10 cm coating. However, when a LED is connected, the current is concentrated near the LED, increasing the resistance. This is a significant effect, resulting in resistance increasing to approximately 50 Ohm for the same 10×10 cm plate. This shows that for a 10×10 cm ITO coating the resistance is barely acceptable. Additionally, when the ITO layer is further patterned the ITO wires become thinner and the resistance increases to unacceptable values.

### Printing Methods

The preferred printing method is silk-screen printing. However, also other printing techniques may be used, such as inkjet printing or offset printing. In offset printing, ink is transferred onto plates and rollers & then onto the glass surface. The resolution achieved in this way is usually better than for silk-screen printing.

### Patterns for the Conductive Wires.

An advantage of the use of printing is that it allows the use of complex connection patterns for driving the LEDs. For example, the invention may be used to lead three wires to an LED for controlling the red/green/blue color of the LED. Alternatively, multiple wires may be used for controlling the color temperature or intensity of the LEDs. The invention may also be used for individual control of the LEDs, by leading a separate wire to each LED on the glass plate, or by adding extra electronics to make a passive or active matrix display.

FIG. 4 shows an example of a complex wire pattern, showing RGB control of two LEDs. In this case the electrodes 3a, 3c and 3d are used for controlling the red, green and blue setting, and electrode 3b is a common electrode connecting to 3a, 3c and 3d through an LED in the LED package 4. Each LED package 4 now contains three LEDs with colors red, green and blue. The bus bar 6b (of FIG. 3) has now been replaced with separate connectors for each LED. It is also possible to use three bus bars, with shared electrodes 3a, 3b, or 3c connected to one bus bar.

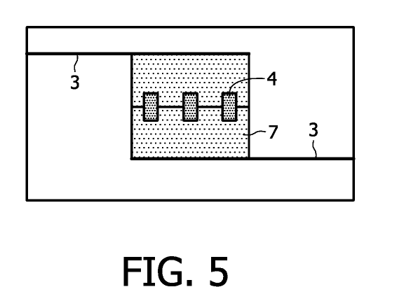

In some cases it may be desired to have certain areas fully transparent. In this case, a combination may be used of silkscreen conductors 3 and fully transparent (for example Indium Tin Oxide) conductors 7 as shown in FIG. 5. This embodiment may for example be used for large glass windows, where an image is displayed in the middle.

Other examples of substantially fully transparent conductors are Indium Zinc Oxide, Tin Oxide or Fluorine Doped Tin Oxide.

Typically, the device comprises many LED devices, embedded in a large glass plate. A typical distance between the LEDs may be from 1 cm to 10 cm.

As will be apparent from the examples above, each electrode gap may be connected by 1 LED, or it may be shared by multiple LEDs.

In the light output device of the invention, the direction of light emission may be from the LED device towards or away from the conductor arrangement, or both. The plurality of light sources can be arranged in a regular array, or they may be arranged in any desired pattern to achieve a given lighting effect.

The transparent substrates may typically be glass or plastic.

As outlined above, the distance between conductive wires and the wire width together define the transparency and resistance. Generally, it is preferred than the spacing is substantially greater than the width, for example at least 10 times greater, and possibly at least 50 times greater or even more than 100 times greater.

The conductor arrangement can include buses to which individual electrode lines are connected.

The example above only shows LED devices integrated into the substrate structure. However, other electronics components, such as microcontrollers or capacitors, may be integrated into the substrate structure. Controllers may be provided for each LED device so that individual external connections are not required to each LED device to enable independent control. Instead, the microcontrollers can communicate as a connected network, and a reduced number of connections then need to pass to the periphery of the device.

Sensors, for example pressure sensors, temperature sensors or light sensors may also be integrated into the structure of the device to give added functionality.

The electrode arrangement can enable individual control of LEDs, for example in an active or passive matrix, or the LEDs may be arranged in groups, which are controlled separately.

The substrates are preferably transparent, but they may also be diffusive. Different light output effects can be obtained with different substrate properties.

Various modifications will be apparent to those skilled in the art.

1. A light output device comprising:
a substrate arrangement comprising:
first and second light transmissive substrates (1,2) and an electrode arrangement (3a,3b) disposed therebetween on a surface of one of the substrates; and
a plurality of light source devices (4) integrated into the structure of the substrate arrangement and connected to the electrode arrangement,
wherein the electrode arrangement comprises an at least semi-transparent conductor arrangement of spaced non-transparent wires, the wires comprising a conductive ink.

2. (canceled)

3. A light output device as claimed in claim 1, wherein the conductor arrangement comprises an ink containing conducting particles.

4. A light output device as claimed in claim 1, wherein the ink comprises silver particles in a thermoplastic binder.

5. A light output device as claimed in claim 1, wherein the ink has a sheet resistance of less than or equal to 0.1 Ohm per square at 0.025 mm thickness.

6. A light output device as claimed in claim 1, wherein the ink has a sheet resistance of less than or equal to 0.075 Ohm per square at 0.025 mm thickness.

7. A light output device as claimed in claim 1, wherein the light source devices are spaced apart by at least 15 mm.

8. (canceled)

9. A light source device as claimed in claim 1, wherein the electrode arrangement comprises a plurality of wires of width more than 75 μm and less than 1000 μm.

10. A light source device as claimed in claim 1, wherein the electrode arrangement comprises a plurality of wires of width more than 150 μm and less than 600 μm.

11-13. (canceled)

14. A light output device as claimed in claim 1, wherein the light source device (4) comprises an LED device or a group of LED devices.

15. A light output device as claimed in claim 14, wherein each light source device (4) comprises a group of three coloured LEDs, and the electrode pattern comprises individual supply electrode lines (3a,3c,3d) leading to each LED

16. A light output device as claimed in claim 1, further comprising a second electrode arrangement having substantially fully transparent electrodes (7) which connect to the electrode arrangement (3).

17-19. (canceled)

20. A method of manufacturing a light output device, comprising:
printing an electrode arrangement (3a,3b) onto a surface of a first light transmissive glass substrate (1) of a substrate arrangement, using a conductive ink, to define a semi-transparent conductor arrangement of non-transparent wires;
providing a plurality of light source devices (4) connected to the electrode arrangement; and
providing a second light transmissive glass substrate (2), and disposing the electrode arrangement between the substrates, thereby integrating the light source devices within the structure of the substrate arrangement.

21. A method as claimed in claim 20, further comprising binding the two substrates together using a thermoplastic layer or resin.

22. A method as claimed in claim 21, wherein the thermoplastic layer or resin comprises polyvinyl butyral or a UV resin.

23. A method as claimed in claim 22, wherein the thickness of the thermoplastic layer or resin ranges from about 0.3 mm to about 2 mm.

24. A method as claimed in claim 20, wherein the ink comprises silver particles in a thermoplastic binder.

25. A method as claimed in claim 20, wherein the printing comprises silk screen printing, inkjet printing, and/or offset printing

26. (canceled)
